(19) United States
(12) Patent Application Publication
(10) Pub. No.: US 2005/0155542 A1
(43) Pub. Date: Jul. 21, 2005

(54) Platform and system for crystal nucleation and growth

(76) Inventors: David Y. Kim, Glenview, IL (US); Sameer Talreja, Champaign, IL (US); Charles F. Zukoski, Urbana, IL (US); Paul J. A. Kenis, Champaign, IL (US)

Correspondence Address: EVAN LAW GROUP LLC, 566 WEST ADAMS, SUITE 350, CHICAGO, IL, 60661, US

(21) Appl. No.: 10/760,144

(22) Filed: Jan. 15, 2004

(51) Int. Cl. C30B 7/02

(52) U.S. Cl. 117/68; 117/70; 422/245.1

(57) ABSTRACT

A method for growing crystals comprises removing solvent from a first plurality of solutions of a compound simultaneously and at substantially the same rate, to form a solid; and removing solvent from a second plurality of solutions of the compound simultaneously and at different rates, to form a solid. The first plurality of solutions contain different concentrations of the compound, and the second plurality of solutions contain substantially the same concentration of the compound.

### FEDERALLY SPONSORED RESEARCH OR DEVELOPMENT

This invention was made with Government support under Contract Number DEFG02-91ER45439 awarded by the Department of Energy—Frederick Seitz Material Research Laboratory. The Government has certain rights in the invention.

### BACKGROUND

Protein structures are strongly correlated with their function in carrying out and mediating complex reaction pathways in all living systems. Failure of these pathways is the cause of diseases such as Alzheimer⁵, Tay-Sachs⁶, and Sandhoff⁶. Information about protein structure is also a key component in rational drug design⁷. In addition, biotechnology thrives on maximizing or manipulating the capability of proteins to produce value-added products⁸. The preferred and most established method to determine three-dimensional protein structures is X-ray diffraction, a technique equally useful for determining the structure of smaller molecules. Obtaining high-quality protein crystals is typically challenging¹, in part because the kinetics of protein crystal nucleation and growth are still poorly understood⁹. Moreover, no methods exist to a priori predict crystal-producing solution conditions, leaving high throughput screening as the only option⁴. Current crystallization screening platforms include two important limitations: they screen only one condition per experiment and the final equilibrium state reached in each experiment does not guarantee the occurrence of a phase transition. Even if the equilibrium phase behavior (i.e. the solubility boundary) is known or can be predicted from measures of the strength of protein-protein attractions¹⁰, crystals may not be observed in a supersaturated solution within a period of time. This observation indicates that not only reaching supersaturation but also the rate of supersaturation is key to a successful crystallization screening method.

Available platforms include microbatch (MB), dialysis, free interface diffusion and hanging drop (HD, a vapor diffusion method). Microbatch screens conditions when protein and precipitant drops are brought in contact, under oil, and conditions are held constant; equilibrium condition is reached almost instantaneously by mixing equal volumes of precipitant and protein solution under oil. Dialysis uses osmotic pressure to change protein-precipitant composition to screen for conditions. Free interface diffusion allows two different solutions, (typically one solution containing the protein to be crystallized and one solution containing salt and/or polymer) to come in contact to form concentration gradients. The protein and precipitants counter-diffuse until equilibrium is reached.

In HD, a droplet (˜2-50 μl) of protein-precipitant mixture hangs over a reservoir (˜500-1000 μl) of the precipitant. This droplet is composed of equal volumes of protein solution and precipitant solution from the reservoir. Water from the droplet diffuses out of the drop and into the reservoir below and equilibrium is achieved when the chemical potential in the droplet is the same as the reservoir (roughly the same precipitant concentration in the drop and the reservoir). The droplet is reduced in volume to almost half of its original volume. The rate of evaporation—and thus the rate of supersaturation—is fast at first, then slowing down and asymptotically approaching the equilibrium condition.

In a related method the rate of equilibration of a drop hanging in a closed evaporation chamber is manipulated by periodic venting¹¹. Others have attempted to control the rate of vapor diffusion by placing parafilm with a small slit or oil in between the droplet and reservoir. More recent technological developments have focused on increasing the throughput for crystallization platforms through rapid-delivery systems¹² and miniaturization, which reduces the amount of sample needed per experiment¹³⁻¹⁵. For example, Quake et al. recently demonstrated the rapid parallel screening of 144 different conditions via free interface diffusion of protein and precipitant solutions in integrated microfluidic networks^{16.}

Current crystallization platforms have limited capabilities; the equilibrium state reached does not guarantee that a phase transition (formation of a gel, liquid-liquid separation, aggregates, crystals, a film, or combinations thereof; also referred to as a “hit”) will occur. In addition, crystals are not typically produced once equilibrium is reached, leaving no definitive end point in the experiment. Typical experiments can take from weeks to months for a phase transition to be observed. If crystallization conditions are identified in the initial screening experiment conditions, then small perturbations are made to those conditions to increase crystal growth or quality (i.e. obtain fewer and larger crystals). Screening methods provide, per experiment, binary information (hit or no-hit) at best and often have a low success rate (typically <20%), requiring a large number of experiments to be performed to find a few suitable crystallization conditions. In addition, the current methods do not provide easy control over the rate of supersaturation.

### BRIEF SUMMARY

In a first aspect, the present invention is a method for growing crystals, comprising removing solvent from a first plurality of solutions of a compound simultaneously, to form solid; and removing solvent from a second plurality of solutions of the compound simultaneously and at different rates, to form solid. The first plurality of solutions contain different concentrations of the compound, and the solvent is removed from the first plurality of solutions at substantially the same rate, prior to forming solid. The second plurality of solutions contain substantially the same concentration of the compound, prior to removing solvent.

In a second aspect, the present invention is a device for growing crystals, comprising a housing forming a plurality of chambers, where each chamber forms a first opening through the housing, and a plurality of evaporation members, where each evaporation member is in gaseous communication with at least one chamber. Each evaporation member has an effective A/L of at most 1 mm.

In a third aspect, the present invention is a kit for growing crystals, comprising a first device, including a first housing forming a plurality of first chambers, where each first chamber forms a first opening through the first housing, and a plurality of first evaporation members, where each first evaporation member is in gaseous communication with at least one of the first chambers. Also part of the kit is a second device, including a second housing forming a plurality of second chambers, where each second chamber forms a first opening through the second housing, and a plurality of second evaporation members, where each second evaporation member is in gaseous communication with at least one of the second chambers. The first and the second evaporation members each have an effective A/L of at most 1 mm, and the first evaporation members each have substantially the same effective A/L. The second evaporation members each have a different A/L.

In a fourth aspect, the present invention is a method for growing crystals, comprising removing solvent from a first plurality of solutions of a compound simultaneously, to form solid; and removing solvent from a second plurality of solutions of the compound simultaneously, to form solid. A third plurality of solutions selected from the group consisting of the first and second pluralities of solutions contain different concentrations of the compound. The solvent is removed at different rates from a fourth plurality of solutions selected from the group consisting of the first and second pluralities of solutions. The solvent is removed from the third plurality of solutions at substantially the same rate, prior to forming solid, and the fourth plurality of solutions contain substantially the same concentration of the compound, prior to removing solvent.

### BRIEF DESCRIPTION OF THE DRAWING

FIG. 1A: Schematic of the present platform.

FIG. 1B: Photograph of the present platform.

FIG. 1C: Photograph of multiple platforms integrated in one slab of material.

FIG. 2. Optical micrographs of screening and protein crystal growth experiment (lysozyme) with the present platform.

FIG. 3. Optical micrographs of screening and protein crystal growth experiment (thaumatin) with present platform.

FIG. 4. Optical micrographs of screening and protein crystal growth experiment (thaumatin) with the present platform.

### DETAILED DESCRIPTION

To overcome the limitation of current crystallization platforms, a platform has been developed that guarantees a phase transition in every experiment to screen for crystallization conditions. Once these conditions have been identified, an independent parameter is available to increase crystal growth and quality for the production of a high quality crystal. This platform uses evaporation of the solvent from a solution (typically a droplet) to the outside environment through an evaporation member (for example, a channel) to drive the solution of the droplet to a condition conducive to a phase transition to occur. Since the final state will typically be a completely desiccated drop, a phase transition may be guaranteed in every experiment.

This platform allows:
(1) rapid identification of crystal producing conditions for compounds, such as proteins, or other chemical or biological molecules, including pharmaceuticals and their precursors, DNA, and RNA;
(2) identification of conditions for crystal growth which will produce the best quality crystals by altering J via (A/L);
(3) rapid identification of multiple crystal morphologies of the same compound;
(4) rapid identification of different hydrates (crystals containing different amounts of water or other solvent molecules) of the same molecule; and
(5) the study of the fundamental physics and chemistry underlying crystal nucleation and growth.

The evaporation rate J represents the rate of volumetric loss of the solvent (at steady state), expressed by the equation

$$J = \frac{KA ( Δ P )}{L}$$

where K is the overall mass transfer coefficient, A the cross-sectional area of the diffusion channel, ΔP the pressure difference between the vapor phase around the drop and the outside environment, and L the length of the diffusion channel. The overall mass transfer coefficient (K) can be described by

$$K = \frac{D}{RT}$$
where D is the diffusivity of the solvent vapor in air, R is the gas constant, and T is the temperature. The temperature and (ΔP) will also affect the evaporation rate as well.

The rate of evaporation will be proportional to A/L of a channel having a uniform cross-sectional area. The evaporation member may be a small hole, an irregularly shaped channel, or even a membrane permeable to vapor of the solvent, in which case the evaporation member will have an effective A/L. The effective A/L can be determined experimentally, by measuring the evaporation rate of the evaporation member, and comparing it to the evaporation rate under identical conditions, using a platform which is otherwise identical except that it has an evaporation member which is a channel having a uniform cross-sectional area, with a known A/L. The term “substantially the same effective A/L” means that the effective A/L of the evaporation members are similar enough that under actual use the variation in the effective A/L does not interfere with determining crystallization conditions, and preferably varies by at most 10%, more preferably by at most 5%. Similarly, the term “substantially the same evaporation rate” means that the evaporation rates are similar enough that under actual use the variation in the evaporation rate does not interfere with determining crystallization conditions, and preferably varies by at most 10%, more preferably by at most 5%. These evaporation rates can change substantially once most of the solvent has evaporated, but is nearly constant prior to the formation of solid.

The vapor pressure around the drop is a weak function of precipitant and protein concentration until very close to complete drying. As a result, ΔP and thus J are nearly constant throughout the course of the evaporation. The experiments thus can be designed to screen a range of supersaturation rates by varying (i) the initial Cₚ and Cₛ, and/or the volume of the drop, and/or (ii) the ratio A/L (or effective A/L), which allows for independent control of J.

The method of rapid identification of crystal producing conditions includes:
(A): identify crystal-producing conditions; and
(B): identify condition for superior crystal quality and growth.
(A) involves varying the initial conditions in the solution that contains the compound to be crystallized (such as a protein) and optionally one or more precipitants (salts such as NaCl, or soluble polymers, etc.). These different solutions are preferably placed in platforms having the same effective A/L (for example, all dimensions and geometries of all cells used are identical, and thus all samples have the same rate of evaporation as determined by the length and cross-sectional area of the channels). Typically this procedure results in different cells exhibiting different phase transitions and/or endpoints: cells may contain varying numbers and sizes of crystals, and/or gel-like skins, and/or gels, and/or amorphous precipitates, etc.
(B) involves varying the rate of evaporation for each experiment, while using the crystal producing conditions identified in (A). In this case each platform used has a different effective A/L (for example, channels of different lengths and or cross-sectional areas). The desired outcome of (B) is one or more platforms containing a small number (1-5) of large crystals of high quality, suitable for structure determination via X-ray diffraction.

Please note, that for (A)—identifying crystal producing conditions—the rate of evaporation may be varied while keeping the initial condition of the solution substantially the same (as in (B), using substantially the same concentration of compound). (B) in this case would then involve varying the initial condition of the solution at the rate of evaporation (or effective A/L) that yielded crystals in (A). It is also possible to initially vary both the rate of evaporation and initial concentration, and then subsequently also vary both the rate of evaporation and initial concentration, each part in a systematic way, to achieve the same result. Here the term “substantially the same concentration” means that the concentrations are similar enough that under actual use the variation does not interfere with determining crystallization conditions, and preferably varies by at most 10%, more preferably by at most 5%.

Part A of this method with the present platform may be completed in 24-48 hours. In contrast, typical experimental times for presently used crystallization platforms are on the order of many days to weeks or even months. Usually one does not know when an experiment is finished in these presently used platforms: a cell that has not produced a crystal, or other phase transition at a certain point in time may or may not exhibit a phase transition at an unknown later point in time. Presently used platforms thus have an expected hit rate (fraction of observed phase transitions) of less than 20%¹⁶. In contrast, the present platform guarantees a phase transition (100% hits) when evaporation is carried out until only solid remains.

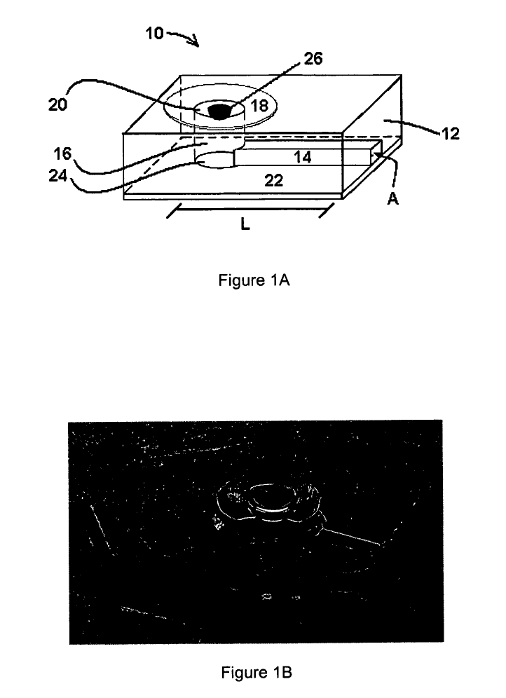

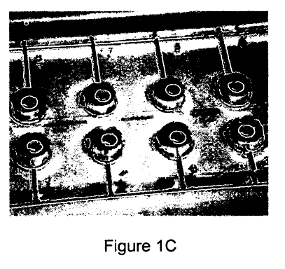

The present platform includes a housing defining a chamber, and an evaporation member. The chamber has an opening for introducing the solution of the compound to be crystallized; this opening is closed off after the solution is in the chamber. The evaporation member defines the path through which gaseous solvent will pass, allowing the solvent to evaporate from the solution. In FIG. 1A, showing an embodiment of the present platform (a device for growing crystals 10), there are three parts in the design (1) an elastomeric polymer slab (or housing 12) containing a molded channel with a length L and a cross-sectional area A (the evaporation member 14), and defining the chamber 16; (2) a top glass slide 18 (which is used to seal the opening 20 in the chamber); and (3) a bottom glass slide 22 (also to seal an opening 24 in the chamber, if a second opening exists). One glass slide typically carries the solution (a drop 26), the other glass slide closes the chamber and typically seals the evaporation member. Alternatively, a polymer sheet or other material can be used to close the compartment. The elastomeric polymer slab serves as the reservoir and controls the geometry of the channel connecting the reservoir to the external atmosphere. The glass slide functions to hold the compound solution and seals the reservoir and the channel so that the evaporation of the solvent only occurs from the reservoir, through the channel, to the outside atmosphere. The geometry of the channel can be designed using replica molding¹⁹. Etching or other surface patterning techniques can be used to design the geometry of the channel. Other materials can be substituted for the elastomeric polymer, such as polystyrene, or other moldable plastics, glass, epoxy resin, silicon, or other materials preferably impermeable to the solvent. Optionally, the housing may be made of a material permeable to the vapor of the solvent, and thereby act as the evaporation member, making the channel unnecessary, or working in combination with a channel or other evaporation member to regulate the evaporation rate.

In FIG. 1, the reservoir was punched out of the elastomer, where the geometry of the reservoir was determined by the thickness of the elastomeric polymer slab and the diameter of the tube used to punch out the chamber. The glass slides were silanized hydrophobic to reduce condensation and maintain the integrity of the solution. Alternatively, the platform can be fabricated by standard machining in materials such as polycarbonate, or by injection molding, or by hot pressing, etc.

This crystallization platform uses one silanized glass slide to hold the protein-precipitant mixture and seal one side of the reservoir. This is similar to the procedure used in the hanging drop platform. The other glass slide seals the other side of the reservoir and the channel connecting the reservoir to the outside air. In FIG. 1A, a schematic of a perspective view is given of such a stacked assembly. The clear block is the polymer, which carries the channel and compartment, with the solution as a hanging drop. The channel with cross-sectional area (A) and length (L) is also shown. The glass slides are also included. FIG. 1B is an optical micrograph of a working platform. The channel connecting the compartment and the outside atmosphere is filled with red ink for photo visualization purposes. FIG. 1C is a photograph of multiple platforms integrated in one housing. Preferably, the housing contains multiple platforms (each platform with a chamber, a channel and an associated solutions); for example at least 6 platforms, or at least 8 platforms, or even at least 10 platforms, including 2-30, 4-25, and 7-20 platforms.

Poly-(dimethylsiloxane) (Sylgard 184, Dow Corning), referred to as PDMS, elastomer was used in the housing as the working platform. Other materials including silicone elastomers, multicomponent epoxy resins, any moldable plastic (polystyrene, polypropylene, etc . . . ), etched glass, or almost any solid material could be used as well. Soft-lithography, such as replica molding, was used to obtain the geometry of the channel. Any other technique, such as etching, milling, hard-lithography, microfabrication or other surface patterning techniques may be used to fabricate the desired geometry as well. Furthermore, the evaporation member may be formed from two slides with side-to-side alignment, or by simply punching a small hole the housing.

Microscope glass coverslips may be used to hold the solution and seal the reservoir and the channel. In the working example, the glass slide was silanized hydrophobic with (tridecafluoro-1,1,2,2-tetrayhyrdooctyl)-1-trichlorosilane. Other forms of silanizing agents can be used to make the glass slide hydrophobic if the solvent is water or hydrophilic. If the solvent is hydrophobic (such as many organic and inorganic solvents), then the glass surfaces would be silanized hydrophilic. Virtually any flat material could be used in place of the glass coverslips. One may also assemble the same crystallization platform from a number of pieces, like a puzzle.

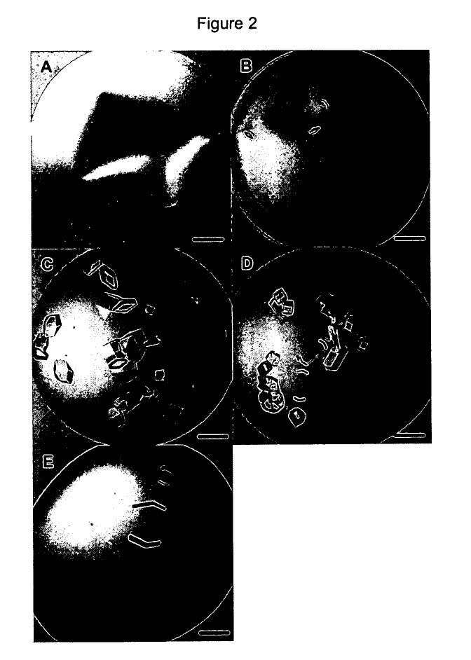

The examples identify suitable conditions for protein crystallization by working with hen egg-white lysozyme protein in an acetate buffer (50 mM, pH 4.6) and sodium chloride (NaCl) as the precipitant. In a two-step experimental procedure crystal-producing conditions were first identified by varying the initial conditions (i.e. Cₚ and Cₛ) at a constant protein/precipitant ratio (Cₚ/Cₛ=30) and evaporation rate (J=0.42 μl/h). Second, superior crystal growth and quality were obtained by varying J at constant initial conditions. Conditions for the first set of experiments are chosen such that the composition of each drop traverses the same path in protein-precipitant composition. The only difference between the experiments was the volume of the drop and thus the rate of change in the concentration of protein and precipitant, i.e. the rate of supersaturation. Since each experiment traverses the same sequence of compositions, if crystal nucleation and growth were solely dependent on the composition, one would expect to observe essentially the same number and size of crystals in each experiment. However, crystals were observed in the most concentrated drop (FIG. 2C; Cₚ=15 mg/ml, Cₛ=0.5M), whereas only a few small crystals and the formation of a film on the surface of the drop were observed for lower initial concentrations (FIG. 2B; Cₚ=7.5 mg/ml, Cₛ=0.25M). For the most dilute protein concentration, only a film was produced (FIG. 2A; Cₚ=3.75 mg/ml, Cₛ=0.125 M). Note that the photographs shown in FIG. 2A-C, were taken at different times. The differences in precipitation state can be understood from the rate of change in the supersaturation S

$$S = \frac{{C}_{p}}{{C}_{sat}} \qquad ( 2 )$$

where Cₛₐₜ is the protein concentration at saturation. S=1 thus corresponds to the solubility boundary. Note that Cₛₐₜ is a function of the precipitant identity (here NaCl) and its concentration (Cₛ), which for lysozyme and many other proteins is well described by
   Cₛₐₜ=Ae^{-B[O]} (3)
where A and B are fitted parameters to solubility data¹⁷. In general, at S>1 no more protein can be dissolved, providing a positive driving force to crystal formation. However, a large energetic barrier at low supersaturation hinders the formation of crystals. This barrier is easily overcome for S>4, the labile region, to produce crystals¹. Gelation or spontaneous nucleation of many crystals that typically contain defects and produce poor diffraction patterns¹⁸ occur at even higher S. The different outcomes of the experiments shown in FIG. 2C (crystals), FIG. 2B (few crystals & film), and FIG. 2A (film only) may be attributed to the increase in the respective rates of supersaturation. The formation of films (FIGS. 2A and 2B) can be explained by the higher evaporation rate resulting in a steep concentration gradient with a high Cₚ at the vapor-liquid interface. This first set of experiments shows that both reaching conditions of S>1 and controlling the rate of supersaturation are important in protein crystallization.

Two methods for systematically varying the rate of supersaturation emerge: (i) increasing the protein and precipitant concentration at constant Cₚ/Cₛ ratio and drop volume (the first set of experiments), and (ii) increasing the volume of the drop at the same Cₚ and Cₛ at constant Cₚ/Cₛ ratio. In the second set of experiments, starting from the just identified crystal-producing condition of FIG. 2C, the evaporation rate was decreased from J=0.42 μl/h (FIG. 2C) to 0.11 μl/h (FIG. 2D) and finally to 0.026 λl/h (FIG. 2E) to yield systematically fewer and larger crystals that visually have fewer defects.

These experiments identify several key characteristics of the present platform: (I) unlike HD and MB, the present platform can guarantee a phase transition in every experiment. As an example, as shown in Table 1, starting with the same initial conditions, only one of the HD experiments resulted in a hit, clusters of crystals with defects and none of the MB experiments resulted in crystals. (II) the present platform can be used to quickly approximate the solubility boundary. The time of nucleation can be determined by continuous monitoring, and since the initial conditions and rate of evaporation are known, the solution condition (i.e. Cₚ and Cₛ) producing the phase transition can be calculated. In HD the rate of equilibration is not known; thus one would need to measure Cₚ at the time of nucleation, a non-trivial task. (III) the experiments also demonstrate that the evaporation rate J, and thus the rate at which the protein solution is supersaturated, is an important parameter for enhancing crystal nucleation, growth and quality. ‘Programming’ HD experiments to have the appropriate J at the point of nucleation is a complex task, especially a priori for new proteins whose very crystallization conditions are to be elucidated. (IV) in the present platform, J is constant by design, whereas in HD J decreases over time. As a result, reaching a phase transition typically takes less time in the present platform than in HD. The present platform more frequently yields a film, however, the observation of a film is a guide indicating the conditions used have resulted in too rapid a rate of supersaturation.

The present platform and the method not only allow for quick determination of solubility boundaries but also reduce the time and the number of experiments needed to obtain high quality protein crystals. Moreover, this platform will also find its usefulness in determining the structure of other biologically relevant molecules such as DNA, RNA and pharmaceuticals.

### EXAMPLES

Fabrication of the platform: The platform was prepared using a rapid prototyping method¹⁹. The master of the platform was obtained via photolithography using 5080-dpi transparency masks and SU-8-100 positive-relief photoresist (Microchem, Boston, Mass.) on 3″ silicon wafers. PDMS elastomer (Sylgard 184, Dow Corning, Midland, Mich.) was used to obtain ˜7-mm thick replicas of the master. A 5-mm through-hole was punched for the evaporation chamber and the PDMS mold was sealed to a microscope cover slip. Typical dimensions: L: 5-10 mm; A: 250×250-1000×1000 μm²; A/L ratios: 200-12.5 μm.

Solutions: Lysozyme protein (Seikagaku America, Falmouth, Mass.) was dissolved in 50 mM acetate buffer (pH 4.6) to obtain a Cₚ of 30 mg/ml. Lower Cₚ solutions were obtained by dilution. A precipitant solution (2M ionic strength) was prepared by adding NaCl to 50 mM acetate buffer. Prior to use the salt and Lysozyme solutions were filtered (0.02 and 0.2 μm-pores, respectively, Anotop 25 and 10, Whatman, Maidstone, England).

Experimental procedure. One or more 10-μl drops of protein-precipitant mixture were pipetted on a silanized glass slide (Hampton, Laguna Niguel, Calif.). Then the glass slide was sealed to the other side of the platform with the droplet(s) positioned in the evaporation chamber(s). The droplets, while stored at ambient conditions, were monitored periodically for a phase transition, which typically occurred in less than 24 hours. Each experiment was performed in fivefold to confirm qualitative outcomes: many small crystals; few, large crystals; film; gel; amorphous precipitate; or combinations of these. Optical micrographs were taken on a Leica MZ-12 stereozoom microscope (Heersbrugs, Switzerland) with a Sony DXC-390 CCD camera (Tokyo, Japan).

Protein 1—Lysozyme

For experiments described below, the protein used was hen egg-white lysozyme (Seigaku America, 6× re-crystallized) in an acetate buffer (pH 4.5, 50 mM). The precipitant used was NaCl salt in the acetate buffer. Different initial conditions were screened with controlled evaporation. All experiments resulted in a phase transition. All figures represent typical phase transitions with the platform (FIG. 2).

### Experiment A—(FIG. 2C)

Chemicals: Hen egg-white lysozyme (Seigaku America 6×re-crystallized), Sodium Acetate and Sodium Chloride salts (Sigma-Aldrich), Glacial Acetic Acid (Fischer), ultrapure MiliQ water (resistance >18 MΩ cm). These chemicals were also used in the experiments below.
Initial conditions: 3.75 mg/ml lysozyme and 0.125 M NaCl in acetate buffer
Evaporation rate: J=0.42 μl/h
Initial drop volume: 10 μl. This initial drop volume was also used in the experiments below.
Channel dimensions: 1 mm² cross-sectional area, 5 mm length

### Experiment B—(FIG. 2B)

Initial conditions: 7.5 mg/ml lysozyme and 0.25M NaCl in acetate buffer
Evaporation rate: same as expt. A
Channel dimensions: same as expt. A

### Experiment C—(FIG. 2A)

Initial conditions: 15 mg/ml lysozyme and 0.5 M NaCl in acetate buffer
Evaporation rate: same as expt. A
Channel dimensions: same as expt. A

### Experiment D—(FIG. 2D)

Initial conditions: 15 mg/ml lysozyme and 0.5 M NaCl in acetate buffer
Evaporation rate: J=0.11 μl/h
Channel dimensions: 0.25 mm² and 5 mm length

### Experiment E—(FIG. 2E)

Initial conditions: 15 mg/ml lysozyme and 0.5 M NaCl in acetate buffer
Evaporation rate: J=0.026 μl/h
Channel dimensions: 0.0625 mm² and 5 mm length

Protein 2—Thaumatin

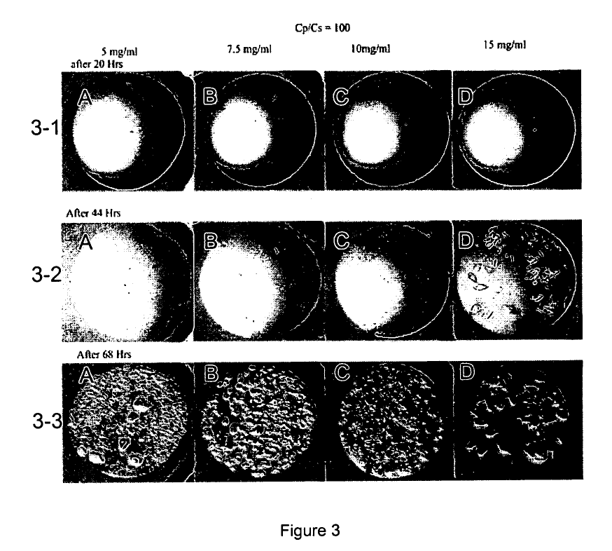

For experiments described below, the protein used was Thaumatin (Sigma-Aldrich America, 3×re-crystallized) in a phosphate buffer (pH 7.0, 50 mM). The precipitant used was NaK tartrate salt in the phosphate buffer. Different initial conditions were screened with controlled evaporation. All experiments resulted in a phase transition. All the images in FIG. 3 represent typical phase transitions with the platform: All figures in 3-1 are after 20 hours, each with different starting concentrations (A=5 mg/ml; B=7.5 mg/ml; C=10 mg/ml; and D=15 mg/ml); all figures in 3-2 are after 44 hours, again each with different starting concentrations (same as in FIG. 3-1); and all figures in 3-3 are after 68 hours, again each with different starting concentrations (same as in FIG. 3-1).

### Experiment α—(FIG. 3A)

Chemicals: Thaumatin (Sigma-Aldrich 3×re-crystallized), Sodium Phosphate and NaK tartrate salts (Sigma-Aldrich), ultrapure MiliQ water (resistance >18 MΩ cm). These chemicals were also used in the experiments below.
Initial conditions: 5 mg/ml thaumatin and 0.05 M NaK tartrate in phosphate buffer
Evaporation rate: 0.11 μl/h
Initial drop volume: 5 μl. This initial drop volume was also used in the experiments below.
Channel dimensions: 0.25 mm² cross-sectional area, 5 mm length

### Experiment β—(FIG. 3B)

Initial conditions: 7.5 mg/ml thaumatin and 0.075M NaK tartrate in phosphate buffer
Evaporation rate: same as expt. α
Channel dimensions: same as expt. α

### Experiment ζ—(FIG. 3C)

Initial conditions: 10 mg/ml thaumatin and 0.10 M NaK tartrate in phosphate buffer
Evaporation rate: same as expt. α
Channel dimensions: same as expt. α

### Experiment δ—(FIG. 3D)

Initial conditions: 15 mg/ml thaumatin and 0.15M NaK tartrate in phosphate buffer
Evaporation rate: same as expt. α
Channel dimensions: same as expt. α

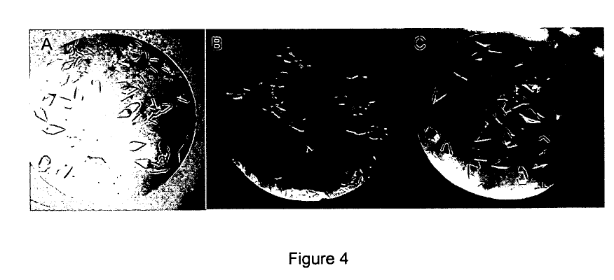

### Experiment ε—(FIG. 4A)

Initial conditions: 15 mg/ml thaumatin and 0.15M NaK tartrate in phosphate buffer
Evaporation rate: same as expt. α
Channel dimensions: same as expt. α

### Experiment φ—(FIG. 4B)

Initial conditions: 15 mg/ml thaumatin and 0.15M NaK tartrate in phosphate buffer
Evaporation rate: 0.055 μl/h
Channel dimensions: 0.25 mm² cross-sectional area, 10 mm length

### Experiment γ—(FIG. 4C)

Initial conditions: 15 mg/ml thaumatin and 0.15M NaK tartrate in phosphate buffer
Evaporation rate: J=0.0367 μl/h

Channel dimensions: 0.25 mm² cross-sectional area, 15 mm length.

TABLE 1
Comparison of results for different crystallization platforms

| Initial | | | | |
|---|---|---|---|---|
| Condition | | | | |
| mg/ml | M | Microbatch (MB)* | Hanging Drop (HD) | Present platform |
| 3.75 | 0.125 | No hit | No hit | Film (FIG. 2A) |
| 7.5 | 0.25 | No hit | No hit | Film with few small crystals (FIG. 2B) |
| 15 | 0.5 | No hit | Few crystals; defects | Many small crystals (FIG. 2C) |
| | | | and clusters present | Few small crystals (FIG. 2D) |
| | | | | Few large crystals (FIG. 2E) |

*Based on lysozyme solubility data for lysozyme in pH 4.6 acetate buffer with NaCl as the precipitant¹⁷ one would have to start at lot higher Cₚ and Cₛ to observe hits in MB. Typically, however, the solubility boundary conditions of a new protein are unknown.

### REFERENCES

1. McPherson, A., Crystallization of Biological Macromolecules. 1 ed. 1999, Cold Spring Harbor: Cold Spring Harbor Laboratory Press. 586.
2. Kanelis, V., J. Forman-Kay, and L. Kay, Multidimensional NMR methods for protein structure deterimination. IUBMB Life, 2001. 52(6): p. 291-302.
3. Thuman-Commike, P., Single particle macromolecular structure determination via electron microscopy. FEBS Letters, 2001. 505(2): p. 199-205.
4. Stevens, R., High-throughput protein crystallization. Current Opinion in Structural Biology, 2000. 10(5): p. 558-563.
5. Steiner, H. and C. Haass, Intramembrane proteolysis by presenilins. Nature Reviews Molecular Cell Biology, 2000. 1(3): p. 217-224.
6. Mark, B., et al., Crystal Structure of Human beta-Hexosaminidase B: Understanding the Molecular Basis of Sandhoff and Tay-Sachs Disease. Journal of Molecular Biology, 2003. 327(5): p. 1093-1109.
7. Stewart, L., R. Clark, and C. Behnke, High-throughput crystallization and structure determination in drug discovery. Drug Discovery Today, 2002. 7(3): p. 187-196.
8. Pfeifer, B., et al., Biosynthesis of complex polyketides in a metabollically engineering strain of Escherichia coli. Science, 2001.291: p. 1790-1792.
9. Anderson, V. J. and H. N. Lekkerkerker, Insights into phase transition kinetics from colloid science. Nature, 2002. 416: p. 811-815.
10. Rosenbaum, D., et al., Protein interactions and phase behavior: Sensitivity to the form of the pair potential. Journal of Chemical Physics, 1999. 111(21): p. 9882-9890.
11. Collingsworth, P., T. Bray, and G. Christopher, Crystal growth via computer controlled vapor diffusion. Journal of Crystal Growth, 2000. 219(3): p. 283-289.
12. Krupka, H., et al., The high-speed Hydra-Plus-One system for automated high-throughput protein crystallography. Acta Crystallographica Section D-Biological Crystallography, 2002. 58(Part 10 Special Issue 1): p. 1523-1526.
13. Howard, E. and R. Cachau, Ink-jet printer heads for ultra-small-drop protein crystallography. Biotechniques, 2002. 33(6): p. 1302-1304.
14. Walter, T., et al., A procedure for setting up high-throughput nanolitre crystallization experiments. 1. Protocol design and validation. Journal of Applied Crystallography, 2003. 36((Part 2)): p. 308-314.
15. Santarsiero, B., et al., An approach to rapid protein crystallization using nanodroplets. Journal of Applied Crystallography, 2002. 35(Part 2): p. 278-281.
16. Hansen, C. L., et al., A robust and scalable microfluidic metering method that allows protein crystal growth by free interface diffusion. Proceedings of the National Academy of Sciences of the United States of America, 2002. 99(26): p. 16531-16536.
17. Rosenbaum, D., P. C. Zamora, and C. F. Zukoski, Phase behavior of small attractive colloidal particles. Physical Review Letters, 1996. 76(1): p. 150-3.
18. Yoshizaki, I., et al., Systematic analysis of the effect of supersaturation on protein crystal quality. Journal of Crystal Growth, 2002. 237(Part1): p. 295-299.
19. Duffy, D., et al., Rapid Prototyping of microfluidic systems in poly(dimethylsiloxane). Analytical Chemistry, 1998. 70(23): p. 4974-4984.

1. A method for growing crystals, comprising:
removing solvent from a first plurality of solutions of a compound simultaneously, to form solid; and
removing solvent from a second plurality of solutions of the compound simultaneously and at different rates, to form solid;
wherein the first plurality of solutions contain different concentrations of the compound,
the solvent is removed from the first plurality of solutions at substantially the same rate, prior to forming solid, and
the second plurality of solutions contain substantially the same concentration of the compound, prior to removing solvent.

2. The method of claim 1, wherein removing solvent from the first plurality of solutions is carried out before removing solvent from the second plurality of solutions.

3. The method of claim 1, wherein removing solvent from the first plurality of solutions is carried out after removing solvent from the second plurality of solutions.

4. The method of claim 1, wherein the rate of removing solvent from the first plurality of solutions, prior to forming solid, varies by at most 10% between each solution of the first plurality.

5. The method of claim 1, wherein the concentration of the compound in the second plurality of solutions varies by at most 10% between each solution of the second plurality, prior to removing the solvent.

6. The method of claim 1, wherein the rate of removing solvent from the first plurality of solutions, prior to forming solid, varies by at most 5% between each solution of the first plurality, and
the concentration of the compound in the second plurality of solutions varies by at most 5% between each solution of the second plurality, prior to removing the solvent.

7. The method of claim 1, wherein removing solvent from the first plurality of solutions is carried out until only solid remains.

8. The method of claim 1, wherein removing solvent from the second plurality of solutions is carried out until only solid remains.

9. The method of claim 2, wherein the concentration of the solutions of the second plurality is substantially the same as the concentration of one of the solutions of the first plurality.

10. The method of claim 3, wherein the rate of removing solvent from the first plurality of solutions, prior to forming solid, is substantially the same as the rate of removing solvent, prior to forming solid, from one of the solutions of the second plurality.

11. The method of claim 1, wherein the compound is a protein.

12. The method of claim 11, wherein the solutions further comprise a precipitant.

13. The method of claim 1, wherein the solvent comprises water.

14. The method of claim 6, wherein the compound is a protein,
the solution further comprises a precipitant, and
the solvent comprises water.

15. The method of claim 13, wherein the solid is a hydrate of the compound.

16. The method of claim 1, wherein the first plurality and the second plurality are each at least six.

17. The method of claim 14, wherein the first plurality and the second plurality are each at least six.

18. A device for growing crystals, comprising:
a housing forming a plurality of chambers, wherein each chamber forms a first opening through the housing, and
a plurality of evaporation members, wherein each evaporation member is in gaseous communication with at least one chamber,
wherein each evaporation member has an effective A/L of at most 1 mm.

19. The device of claim 18, wherein the evaporation members are channels in the housing, each having a length of at most 100 mm, and a cross-sectional area of at most 1 mm².

20. The device of claim 19, wherein each chamber has a volume of at most 1700 mm³.

21. The device of claim 20, wherein each chamber has a volume of at most 350 mm³, and each channel has an A/L of at most 400 μm.

22. The device of claim 20, wherein each chamber forms a second opening through the housing, and each channel is a groove in the housing.

23. The device of claim 20, wherein the housing comprises at least 6 chambers.

24. The device of claim 20, wherein each of the channels has the same effective A/L.

25. The device of claim 20, wherein each of the channels has a different A/L.

26. A kit for growing crystals, comprising:
a first device, comprising:
a first housing forming a plurality of first chambers, wherein each first chamber forms a first opening through the first housing, and
a plurality of first evaporation members, wherein each first evaporation member is in gaseous communication with at least one of the first chambers,
a second device, comprising:
a second housing forming a plurality of second chambers, wherein each second chamber forms a first opening through the second housing, and
a plurality of second evaporation members, wherein each second evaporation member is in gaseous communication with at least one of the second chambers,
wherein the first and the second evaporation members each have an effective A/L of at most 1 mm,
the first evaporation members each have substantially the same effective A/L, and
the second evaporation members each have a different A/L.

27. The kit of claim 26, wherein the evaporation members are channels in the housing, each having a length of at most 100 mm, and a cross-sectional area of at most 1 mm².

28. The kit of claim 26, wherein each chamber has a volume of at most 1700 mm³.

29. The kit of claim 27, wherein each chamber has a volume of at most 350 mm³, and each channel has an A/L of at most 400 μm.

30. The kit of claim 27, wherein each chamber forms a second opening through the housing, and each channel is a groove in the housing.

31. The kit of claim 26, wherein the first and the second housings each comprises at least 6 chambers.

32. A method for growing crystals, comprising:
removing solvent from a first plurality of solutions of a compound simultaneously, to form solid; and
removing solvent from a second plurality of solutions of the compound simultaneously, to form solid;
wherein a third plurality of solutions selected from the group consisting of the first and second pluralities of solutions contain different concentrations of the compound,
the solvent is removed at different rates from a fourth plurality of solutions selected from the group consisting of the first and second pluralities of solutions,
the solvent is removed from the third plurality of solutions at substantially the same rate, prior to forming solid, and
the fourth plurality of solutions contain substantially the same concentration of the compound, prior to removing solvent.

33. The method of claim 32, wherein removing solvent from the first plurality of solutions is carried out before removing solvent from the second plurality of solutions.

34. The method of claim 32, wherein removing solvent from the first plurality of solutions is carried out after removing solvent from the second plurality of solutions.

35. The method of claim 32, wherein the rate of removing solvent from the third plurality of solutions, prior to forming solid, varies by at most 10% between each solution of the third plurality.

36. The method of claim 32, wherein the concentration of the compound in the fourth plurality of solutions varies by at most 10% between each solution of the fourth plurality, prior to removing the solvent.

37. The method of claim 32, wherein the rate of removing solvent from the third plurality of solutions, prior to forming solid, varies by at most 5% between each solution of the third plurality, and
the concentration of the compound in the fourth plurality of solutions varies by at most 5% between each solution of the fourth plurality, prior to removing the solvent.

38. The method of claim 32, wherein removing solvent from the first plurality of solutions is carried out until only solid remains.

39. The method of claim 32, wherein removing solvent from the second plurality of solutions is carried out until only solid remains.

40. The method of claim 33, wherein the concentration of the solutions of the fourth plurality is substantially the same as the concentration of one of the solutions of the third plurality.

41. The method of claim 32, wherein the compound is a protein.

42. The method of claim 41, wherein the solutions further comprise a precipitant.

43. The method of claim 32, wherein the solvent comprises water.

44. The method of claim 37, wherein the compound is a protein,
the solution further comprises a precipitant, and
the solvent comprises water.

45. The method of claim 32, wherein the first plurality and the second plurality are each at least six.
